(19) United States
(12) Patent Application Publication
(10) Pub. No.: US 2019/0206715 A1
(43) Pub. Date: Jul. 4, 2019

(54) PROCESSING APPARATUS

(71) Applicant: DISCO CORPORATION, Tokyo (JP)

(72) Inventor: Hiroto YOSHIDA, Tokyo (JP)

(21) Appl. No.: 16/239,902

(22) Filed: Jan. 4, 2019

(30) Foreign Application Priority Data
Jan. 4, 2018 (JP) 2018-000227

(51) Int. Cl. H01L 21/687; B05D 1/00; H01L 21/67; H01L 21/683; H01L 21/78

(52) U.S. Cl. CPC H01L 21/68721; B05D 1/005; H01L 21/68764; H01L 21/67051; H01L 21/6836; H01L 21/78; H01L 21/6838; H01L 21/6715

(57) ABSTRACT

A processing apparatus includes a holding unit adapted to hold a frame unit, the frame unit including a ring frame formed with four sides at an interval of 90 degrees along an outer circumference of an annular plate having an opening for accommodating a wafer, the wafer being secured to the ring frame through an adhesive tape. The holding unit includes four claw sections. Each of the claw sections includes a tip portion such that the spacing between two opposed claw sections is larger than the distance between the opposed two sides of the ring frame and is smaller than the diameter of an outermost circumference of the ring frame, and a base portion. The base portion is formed with a fixing groove in which to fix the ring frame by rotating the frame unit in a direction opposite to the direction of rotation of the holding unit.

### BACKGROUND OF THE INVENTION

### Field of the Invention

The present invention relates to a processing apparatus for processing a wafer.

### Description of the Related Art

In the semiconductor device manufacturing process, a semiconductor wafer formed with a plurality of devices is divided along division lines (streets) by a cutting apparatus, thereby forming semiconductor chips. The wafer is supported on a ring frame through a tape adhered to the ring frame in the manner of closing an opening, and, in this state, the wafer is carried into the cutting apparatus. Then, in a state in which the frame unit of the ring frame and the wafer united together is held by a holding table, the wafer is cut by a cutting blade.

After the cutting, the frame unit is carried to a cleaning mechanism, and is held by a spinner table. Then, the spinner table is spun while cleaning water is being supplied to the wafer, whereby the wafer is cleaned. Thereafter, while spinning of the spinner table is continued, the supply of the cleaning water to the wafer is switched to the supply of air, whereby the cleaning water is blown off from the wafer, and the wafer is dried.

Since the spinning of the spinner table is at high speed, the ring frame is grasped by centrifugal clamps disposed in the periphery of the spinner table such that lateral slippage of the frame unit held by the spinner table does not occur during the spinning (see, for example, Japanese Patent Laid-open No. 2013-115234). The centrifugal clamps are pendulum-like clamps connected to four sides of the spinner table, and, during spinning of the spinner table, weight portions of the centrifugal clamps are made to spring up by a centrifugal force, to clamp the ring frame.

### SUMMARY OF THE INVENTION

However, since the centrifugal clamps are also rotated by the spinning of the spinner table, air turbulence is generated inside the cleaning mechanism due to the rotation of the weight portions having a large sectional area. The air turbulence causes the cleaning water blown off from the wafer at the time of drying to adhere again to the wafer, thereby contaminating the wafer.

In addition, a spinner table is used also in a protective film coating apparatus for forming a protective film on a wafer upper surface by spin coating. A liquid resin is supplied to the center of the upper surface of a wafer held by the spinner table, and the spinner table is spun, to move the liquid resin toward the periphery of the wafer by a centrifugal force, thereby forming the protective film on the upper surface of the wafer. In this case, by air turbulence generated due to the rotation of the centrifugal clamps, the surplus liquid resin blown off from the wafer is made to adhere again to the wafer, so that the thickness of the protective film becomes uneven.

It is therefore an object of the present invention to provide a processing apparatus by which lateral slippage of a ring frame on holding means is prevented and generation of air turbulence at the time of rotation of the holding means is restrained.

In accordance with an aspect of the present invention, there is provided a processing apparatus which includes holding means holding a frame unit, the frame unit including a ring frame formed with four sides at an interval of 90 degrees along an outer circumference of an annular plate having an opening for accommodating a wafer, the wafer accommodated in the ring frame and united with the ring frame through an adhesive tape, and which performs a predetermined treatment by rotating the holding means and supplying a liquid to the wafer, in which the holding means includes: a wafer holding section adapted to suction hold a wafer region; and four claw sections corresponding to the four sides of the ring frame, each of the four claw sections includes a tip portion formed such that spacing between opposed two claw sections among the four claw sections is larger than distance between opposed two sides of the ring frame and is smaller than a diameter of an outermost circumference of the ring frame, and a base portion adapted to support the ring frame, and the base portion is formed with a fixing groove in which to fix the ring frame by rotating the accommodated frame unit in a direction opposite to the direction of rotation of the holding means.

According to this configuration, the spacing between the opposed two tip portions of the claw sections is formed to be larger than the distance between the opposed two sides of the ring frame and to be smaller than the diameter of the outermost circumference of the ring frame. This ensures that by coinciding the positions of the four sides of the ring frame and the positions of the four claw sections, the frame unit can be placed on the holding means without collision between the ring frame and the tip portions. In addition, when the frame unit supported by the base portions is rotated in a direction opposite to the rotating direction of the holding means to bring the outermost circumference of the ring frame into contact with the claw sections and the holding means is rotated in this state, an inertial force is generated in the ring frame in the direction opposite to the rotating direction of the holding means, and the outermost circumference of the ring frame continues contacting the claw sections. Therefore, the ring frame can be fixed to the fixing grooves, and lateral slippage of the frame unit on the holding means can be prevented. Since it is thus unnecessary to clamp the ring frame by a centrifugal force by use of weight portions having a large sectional area of centrifugal clamps, generation of air turbulence during rotation of the holding means is restrained, and scattering of the liquid supplied to the wafer by the air turbulence is prevented. Accordingly, contamination of the wafer with the scattered liquid can be prevented.

Preferably, the processing apparatus further includes: a carrying unit that suction holds an upper surface of the ring frame and carries the frame unit to the holding means; lifting means lifting up and down the carrying unit in a direction orthogonal to a holding surface of the wafer holding section; and a control section that controls an operation of the holding means, in which the control section includes a fixation recognition section adapted to recognize that the ring frame is held by the carrying unit, and is lowered from above the holding means by the lifting means, and the holding means is rotated in a direction for performing a predetermined treatment around a center of the holding surface, to cause the fixing grooves to fix the ring frame.

Preferably, the carrying unit includes a moving unit adapted to move in a direction of the holding surface, and a center of the frame unit and the center of the holding surface are made to coincide with each other when the fixing grooves fix the ring frame.

According to the present invention, lateral slippage of the ring frame on the holding means is prevented, and the generation of air turbulence during rotation of the holding means is restrained.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a cutting apparatus according to an embodiment of the present invention;

FIG. 2 is a perspective view of a second carrying unit according to the present embodiment;

FIG. 3 is a perspective view of a spinner table according to the present embodiment;

FIGS. 4A and 4B are upper views of holding means according to the present embodiment;

FIGS. 5A and 5B are side views of a claw section according to the present embodiment;

FIGS. 6A and 6B are plan views for explaining a fixing operation of a ring frame in the claw section according to the present embodiment;

FIGS. 7A to 7C are side views for explaining a centering of a moving unit according to the present embodiment;

FIGS. 8A and 8B are sectional views of a fixing mechanism for the ring frame and plan views for explaining flows of air when a spin table is spun by use of the same;

FIGS. 9A and 9B are perspective views for explaining a rotatable unit according to the present embodiment; and

FIGS. 10A to 10C are schematic figures for explaining an operation of the rotatable unit according to the present embodiment.

### DETAILED DESCRIPTION OF THE PREFERRED EMBODIMENTS

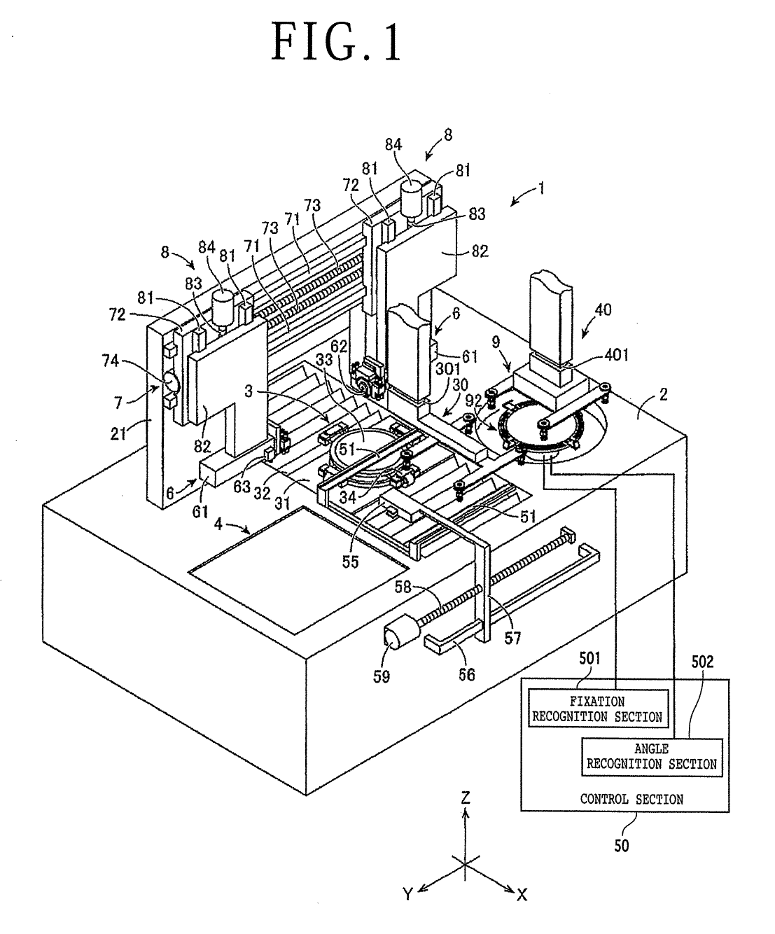

A cutting apparatus according to an embodiment of the present invention will be described below, referring to the attached drawings. FIG. 1 is a perspective view of the cutting apparatus according to the present embodiment. Note that while the cutting apparatus is described as an example of a processing apparatus, the processing apparatus is not particularly limited, provided that it includes a spinner table.

As illustrated in FIG. 1, the cutting apparatus 1 is configured such as to cut a wafer W by relatively moving a pair of cutting units 6 which each have a cutting blade 62 and a holding table 3 which holds the wafer W. The wafer W after cutting is held by a spinner table 92 of a spinner cleaning mechanism 9, and cleaning water is jetted to the spinner table 92 in rotation, to perform cleaning.

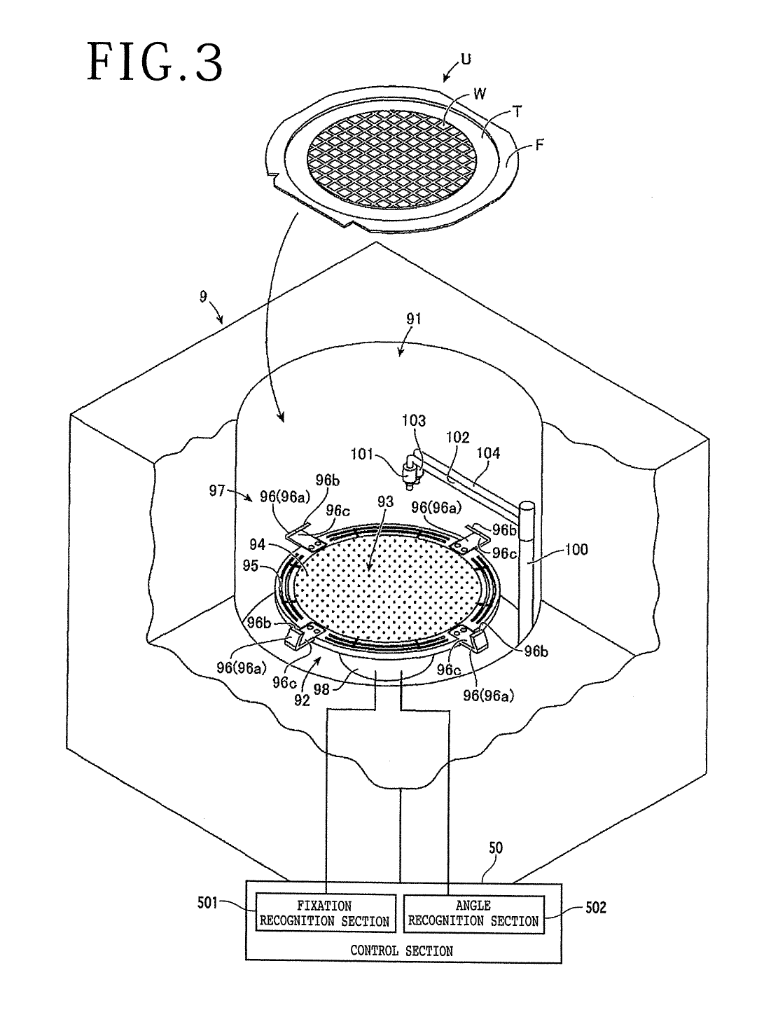

The wafer W is carried into the cutting apparatus 1 in the state of being supported by a ring frame F through an adhesive tape T (see FIG. 3). Four sides (rectilinear portions) are formed at an interval of 90 degrees along an outer circumference of the ring frame F, and the ring frame F is formed in its center with an opening in which to accommodate the wafer W. The adhesive tape T is adhered to the ring frame F such as to close the opening. The wafer W is accommodated in the opening of the ring frame F, and is adhered onto the adhesive tape T and united with the ring frame F, to form a frame unit U.

Note that the wafer W is roughly disk-shaped, and may be any of various wafers such as a semiconductor substrate, an inorganic material substrate, and a package substrate. As the semiconductor substrate, there may be used various substrates of silicon, gallium arsenide, gallium nitride, silicon carbide and the like. As the inorganic material substrate, there may be used any of various substrates of sapphire, ceramics, glass and the like. The semiconductor substrate and the inorganic material substrate may be formed with devices or may not be formed with devices. As the package substrate, there may be used any of various packages for Chip Size Package (CSP), Wafer Level Chip Size Package (WLCSP), Electro Magnetic Interference (EMI), System In Package (SIP), or Fan Out Wafer Level Package (FOWLP). In addition, as the wafer W, there may be used lithium tantalate, lithium niobate, green ceramics, and piezoelectric elements after or before formation of devices.

A base 2 of the cutting apparatus 1 is provided in the center of an upper surface thereof with a rectangular opening extending in an X-axis direction, and a moving plate 31 and a waterproof cover 32 are provided in the manner of covering the opening. On the moving plate 31 is provided a holding table 3 which can be rotated around a Z axis. Under the waterproof cover 32 and the moving plate 31 is provided processing feeding means (not illustrated) moving the holding table 3 in the X-axis direction. At an upper surface of the holding table 3 is formed a holding surface 33 from a porous ceramic material, and the wafer W is suction held by a negative pressure generated at the holding surface 33. Four clamps 34 of an air drive type are provided in the periphery of the holding table 3, and the ring frame F in the periphery of the wafer W is fixed by being clamped from four sides by the clamps 34. On the upper side of the holding table 3 are provided a pair of centering guides 51 extending in a Y-axis direction. The pair of centering guides 51 are brought closer to and away from each other in the X-axis direction, whereby the wafer W is positioned in the X-axis direction relative to the holding table 3.

An elevator unit 4 on which to place a cassette (not illustrated) is provided on the base 2 adjacently to the holding table 3. At the elevator unit 4, the cassette is lifted up and down, whereby a letting-in/out position for the frame unit U in the cassette is adjusted in the height direction.

A push-pull arm 55 that lets the frame unit U in and out of the cassette while guiding the ring frame F by the pair of centering guides 51 is provided adjacent to the elevator unit 4. The push-pull arm 55 is driven by a horizontal moving mechanism disposed on a side surface of the base 2. The horizontal moving mechanism includes a guide rail 56 disposed on a side surface of the base 2 and parallel to the Y-axis direction, and a motor driven type slider 57 disposed on the guide rail 56 in a slidable manner. The slider 57 is formed with a nut section, and a ball screw 58 is in screw engagement with the nut section. When a drive motor 59 connected to one end portion of the ball screw 58 is rotationally driven, the push-pull arm 55 performs a push/pull operation in the Y-axis direction along the guide rail 56.

In addition, a gate-formed column section 21 erected in the manner of straddling the opening extending in the X-axis direction is provide on the upper surface of the base 2. The gate-formed column section 21 is provided with indexing feeding means 7 moving the pair of cutting units 6 in the Y-axis direction, and cutting-in feeding means 8 moving the pair of cutting units 6 in the Z-axis direction. The indexing feeding means 7 includes a pair of guide rails 71 disposed on a front surface of the column section 21 and parallel to the Y-axis direction, and a pair of motor-driven type Y-axis tables 72 disposed on the pair of guide rails 71 in a slidable manner. The cutting-in feeding means 8 includes a pair of guide rails 81 disposed on the front surfaces of the Y-axis tables 72 and parallel to the Z-axis direction, and a motor-driven type Z-axis table 82 disposed on the pair of guide rails 81 in a slidable manner.

The cutting unit 6 adapted to cut a work W is provided at a lower portion of each Z-axis table 82. A nut section (not illustrated) is formed on a back surface side of each Y-axis table 72, and a ball screw 73 is in screw engagement with these nut sections. In addition, a nut section (not illustrated) is formed on a back surface side of each Z-axis table 82, and a ball screw 83 is in screw engagement with these nut sections. Drive motors 74 and 84 are respectively connected to one-side end portions of the ball screws 73 for the Y-axis tables 72 and the ball screws 83 for the Z-axis tables 82. With the ball screws 73 and 83 rotationally driven by these drive motors 74 and 84, the pair of cutting units 6 are moved in the Y-axis direction and the Z-axis direction along the guide rails 71 and 81.

The pair of cutting units 6 are each configured by rotatably mounting a cutting blade 62 to a tip of a spindle (not illustrated) projecting from a housing 61. The cutting blade 62 is formed in a disk shape, for example, by binding diamond abrasive grains with a resin bond. The housing 61 of the cutting unit 6 is provided with an imaging unit 63 adapted to image the upper surface of the work W, and the cutting blade 62 is aligned to the work W, on the basis of an image picked up by the imaging unit 63. The pair of cutting units 6 cut the wafer W by the cutting blades 62 while jetting cutting water from cutting nozzles (not illustrated) to the work W.

In addition, a spinner cleaning mechanism 9 is provided on the opposite side of the opening of the base 2 from the elevator unit 4. A spinner table 92 which rotates while holding the frame unit U is accommodated in the spinner cleaning mechanism 9. The spinner table 92 includes holding means (see FIG. 3) holding the frame unit U. At the spinner cleaning mechanism 9, cleaning water is jetted toward the spinner table 92 in rotation, to clean the wafer W, after which dry air is blown in place of the cleaning water, to dry the wafer W.

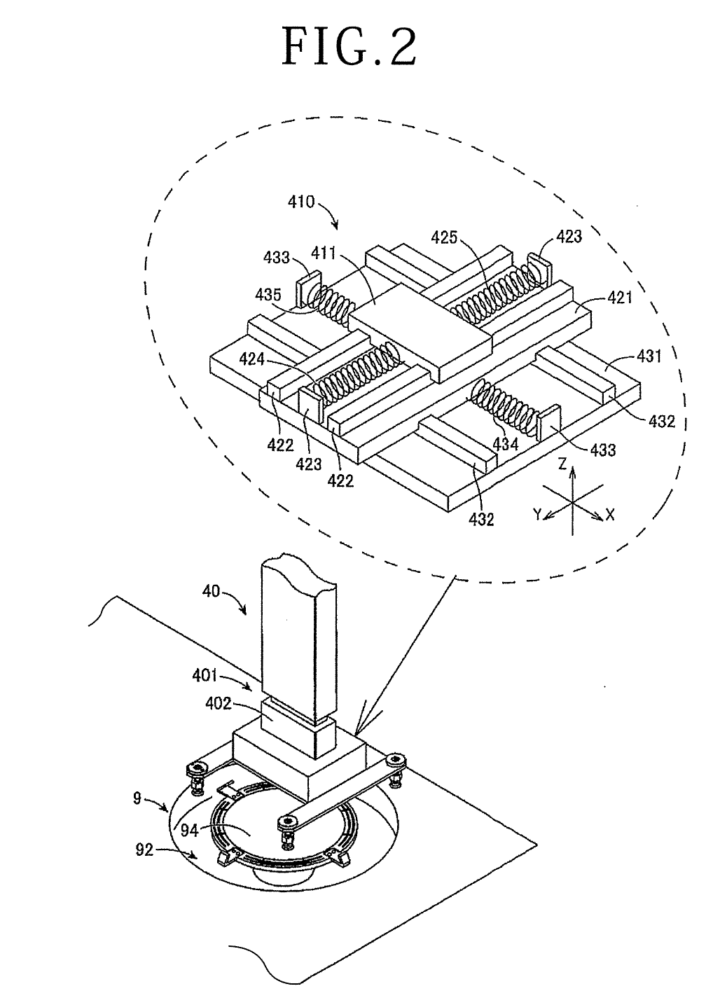

A first carrying unit 30 and a second carrying unit 40 are provided on the upper side of the base 2. The first carrying unit 30 suction holds an upper surface of the ring frame F of the frame unit U taken out of the cassette by the push-pull arm 55 and disposed at the pair of centering guides 51, and carries the frame unit U to the holding table 3. The second carrying unit 40 suction holds the upper surface of the ring frame F of the frame unit U held by the holding table 3, after the wafer W is cut by the cutting unit 6, and carries the frame unit U to the spinner table 92. The first carrying unit 30 is driven by the horizontal moving mechanism (not illustrated) to move in the Y-axis direction for carrying, and is lifted up or down in a direction for spacing away from the holding surface 33 of the holding table 3 by lifting means 301. The second carrying unit 40 is driven by the horizontal moving mechanism (not illustrated) to move in the Y-axis direction for carrying, and is lifted up or down in a direction for spacing away from the holding surface 94 (see FIGS. 2 and 3) of the spinner table 92 by lifting means 401.

In addition, the cutting apparatus 1 is provided with a control section 50 that supervisingly controls each part of the apparatus. Besides, the control section 50 is provided with a fixation recognition section 501 and an angle recognition section 502 which will be described later. The control section 50 includes a processor adapted to execute various processings, a memory and the like. The memory includes one or a plurality of storage media such as a Read Only Memory (ROM) and a Random Access Memory (RAM) according to use.

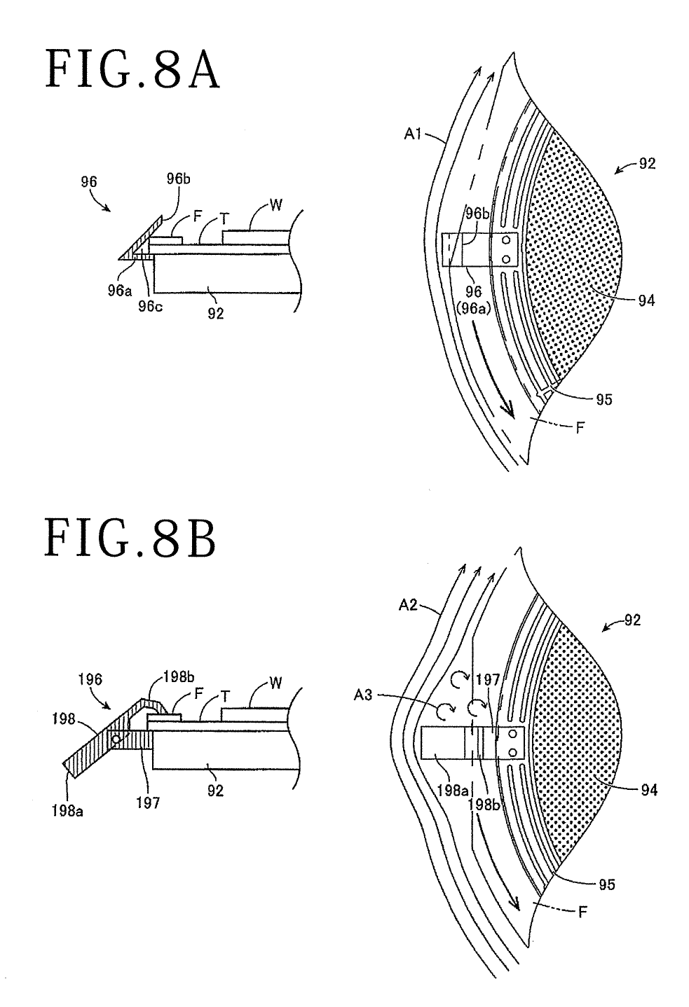

Here, in general, centrifugal clamps are arranged in the periphery of a spinner table, and the ring frame is clamped by the centrifugal clamps such as to prevent lateral slippage of the frame unit during spinning. The centrifugal clamp is formed with a claw section at an upper portion and with a weight portion at a lower portion, and the weight portion is made to spring up by a centrifugal force during spinning, whereby the ring frame is pressed by the claw section, to restrain lateral slippage of the ring frame (see FIG. 8B). However, since the weight portion large in sectional area is rotated, air turbulence is generated in the spinner cleaning mechanism, and the cleaning water blown away from the wafer at the time of drying is re-adhered to the wafer due to the air turbulence, resulting in the problem of contamination of the wafer. In view of this, in the present embodiment, a mechanism for fixing the ring frame is simplified, and a configuration in which the frame unit can be fixed without using the weight portions is adopted, whereby generation of air turbulence is restrained.

Referring to FIGS. 2 to 5B, a fixing mechanism for the ring frame will be described. First, referring to FIG. 2, the configuration of the second carrying unit 40 will be described in detail. FIG. 2 is a perspective view of the second carrying unit according to the present embodiment.

As illustrated in FIG. 2, the second carrying unit 40, in the state of suction holding the upper surface of the ring frame F of the frame unit U (see FIG. 3), is lifted up or down in a direction orthogonal to the holding surface 94 of the spinner table 92 by the lifting means 401, and places the frame unit U on the holding surface 94. The second carrying unit 40 is provided at a lower portion thereof with a moving unit 410 that permits movement of the frame unit U in the direction of the holding surface 94, or the direction parallel to the holding surface 94.

The moving unit 410 is formed such as to permit movement of an intermediate-stage X-axis table 421 in the X-axis direction relative to an upper-stage fixed table 411, and to permit movement of a lower-stage Y-axis table 431 in the Y-axis direction. Ring frame support sections 441 and 442 are provided respectively at side surfaces of the Y-axis table 431, and the ring frame F is suction held by suckers provided in the ring frame support sections 441 and 442.

A pair of guide rails 422 parallel to the Y-axis direction are disposed on the upper surface of the X-axis table 421, and the fixed table 411 is disposed slidably through the pair of guide rails 422. The fixed table 411 is connected to a moving unit support section 402 of the second carrying unit 40. A pair of spring support sections 423 are disposed between the pair of guide rails 422, and spring members 424 and 425 are each provided between each spring support section 423 and the fixed table 411. One end of each of the spring members 424 and 425 is supported by the spring support section 423, and the other ends are connected to side surfaces of the fixed table 411.

In addition, a pair of guide rails 432 parallel to the X-axis direction are disposed on the upper surface of the Y-axis table 431, and the X-axis table 421 is disposed slidably through the pair of guide rails 432. A pair of spring support sections 433 are disposed between the pair of guide rails 432, and spring members 434 and 435 are each provided between each spring support section 433 and the X-axis table 421. One end of each of the spring members 434 and 435 is supported by the spring support section 433, and the other ends are connected to side surfaces of the X-axis table 421.

With the spring members 434 and 435 expanded and contracted in the X-axis direction, movement of the X-axis table 421 in the X-axis direction relative to the fixed table 411 is permitted. With the spring members 424 and 425 expanded and contracted in the Y-axis direction, movement of the Y-axis table 431 in the Y-axis direction relative to the fixed table 411 is permitted. Thus, movements of the ring frame support sections 441 and 442 from the moving unit support section 402 in the X-axis direction and the Y-axis direction are permitted by the moving unit 410, and, therefore, movements of the ring frame F suction held by the ring frame support sections 441 and 442 in the X-axis direction and the Y-axis direction are permitted. Accordingly, by lowering the frame unit U to the holding surface 94 by the second carrying unit 40 and thereafter bringing the ring frame F into contact with the claw section 96 to be described later, the center position of the frame unit U located in the center of the holding surface 94 is adjusted, and the center of the frame unit U can be made to coincide with the center of the holding surface 94.

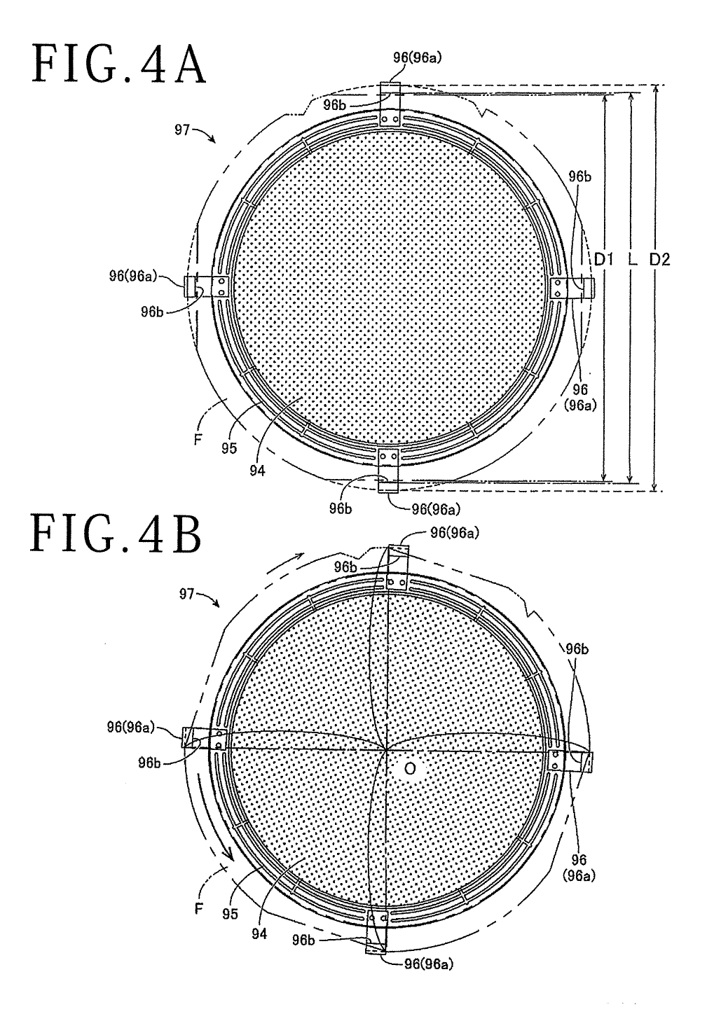

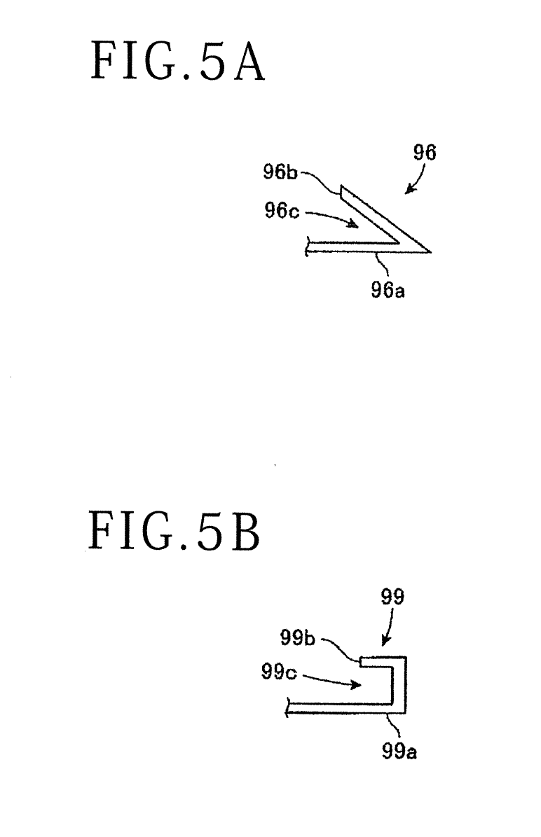

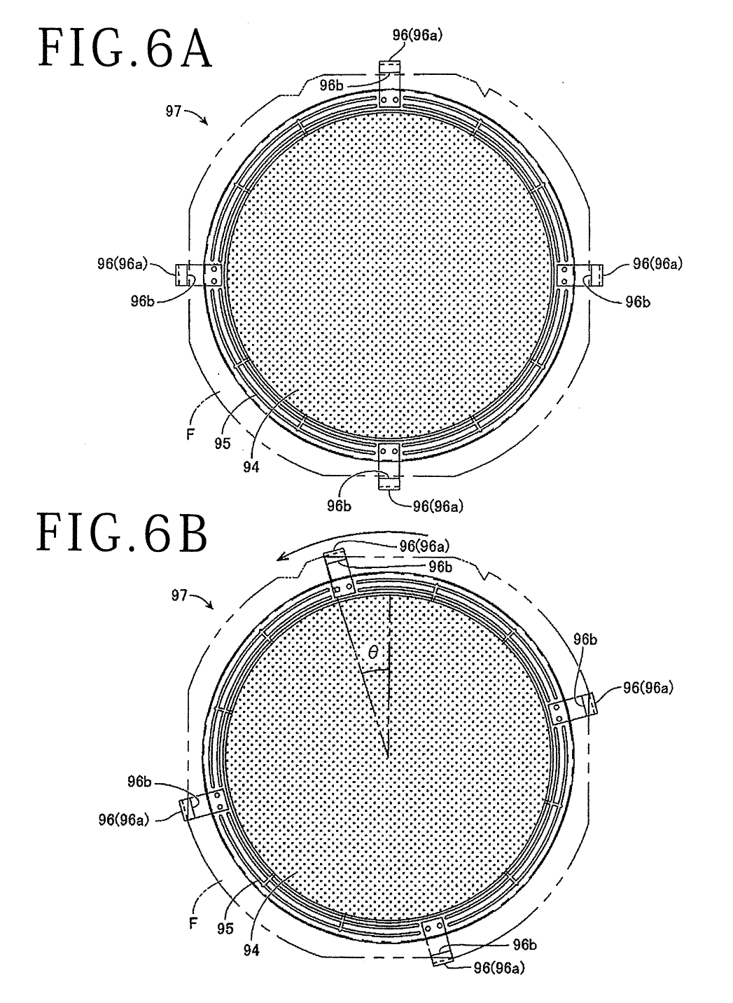

The configuration of the holding means for the frame unit in the spinner table will be described in detail below, referring to FIGS. 3 to 5B. FIG. 3 is a perspective view of the spinner table according to the present embodiment. FIGS. 4A and 4B are upper views of the holding means according to the present embodiment. FIGS. 5A and 5B are side views of the claw section according to the present embodiment. In FIG. 4A, the broken lines indicate the diameter of an outermost circumference of the ring frame F. In addition, the alternate long and two short dashes line indicates the ring frame F in the frame unit U placed on the spinner table 92. The same applies also to FIGS. 6A and 8A.

As illustrated in FIG. 3, a cleaning case 91 of the spinner cleaning mechanism 9 is formed in a bottomed tubular shape having a cylindrical peripheral wall. In addition, the spinner table 92 adapted to hold and rotate the wafer W is accommodated in the cleaning case 91. On the upper side of the spinner table 92, there are provided a cleaning water supply nozzle 101 for supplying cleaning water to the frame unit U held by the spinner table 92 and an air supply nozzle 103 for supplying air.

The upper surface of the spinner table 92 is a wafer holding section 93 adapted to suction hold the frame unit U. A holding surface 94 adapted to suction hold the wafer W region of the frame unit U is formed in the center of the wafer holding section 93, and an adhesive tape suction surface 95 adapted to suction hole the adhesive tape T is formed at the periphery of the wafer holding section 93. In addition, the wafer holding section 93 is provided with claw sections 96, and the wafer holding section 93 and the claw sections 96 form holding means 97 holding the frame unit U. The spinner table 92 is configured to be rotatable around the center of the holding surface 94 of the wafer holding section 93 by rotating means 98.

The holding surface 94 has an area corresponding to the area of the wafer W. Besides, the holding surface 94 is formed of a porous ceramic material, and the wafer W is suction held through the adhesive tape T by a negative pressure generated at the holding surface 94. The adhesive tape suction surface 95 formed at the periphery of the holding surface 94 is formed with suction grooves, the suction grooves communicate with the porous ceramic material of the holding surface 94, and a negative pressure is generated in the suction grooves due to the negative pressure at the holding surface 94, whereby the adhesive tape T region between the ring frame F and the wafer W is suction held.

The four claw sections 96 are connected to four sides of the wafer holding section 93. The four claw sections 96 correspond to the positions of the four sides of the ring frame F at the time when the frame unit U is placed on the wafer holding section 93. Further, the claw sections 96 are bent toward the center of the holding surface 94 and are each formed with a base portion 96a which supports the ring frame F and a tip portion 96b which is bent.

As depicted in FIG. 4A, in the tip portions 96b, the spacing L between the tip portions 96b of the opposed two claw sections 96 of the four claw sections 96 is larger than the distance D1 between the opposed two sides of the ring frame F and is smaller than the diameter D2 of an outermost circumference of the ring frame F. This ensures that when the frame unit U is placed on the wafer holding section 93, the positions of the four sides of the ring frame F and the positions of the four claw sections 96 coincide with each other, whereby the ring frame F can be accommodated inside the claw sections 96, without collision between the ring frame F and the tip portions 96b.

In addition, the claw section 96 is formed with a fixing groove 96c inside a bent portion thereof (FIG. 5A). The fixing grooves 96c are formed in such a manner that, when the ring frame F is rotated in a direction (short arrow) reverse to a direction (long arrow) of rotation of the spinner table 92 after the ring frame F is accommodated inside the claw sections 96, as depicted in FIG. 4B, the outermost circumference of the ring frame F makes contact with the fixing grooves 96c. By this, the ring frame F is fixed to the fixing grooves 96c, and, therefore, lateral slippage of the frame unit U on the holding means 97 can be prevented.

Besides, when the outermost circumference makes contact with the claw sections 96, the distance from the contact point between the claw section 96 and the outermost circumference of the ring frame F to the center O of the frame unit U is equal for all the claw sections 96, so that the center O of the frame unit U and the center of the wafer holding section 93 coincide with each other. This ensures that the frame unit U is held in a state of being positioned by the holding means 97 of the spinner table 92, and, therefore, eccentricity of the frame unit U is prevented from occurring during spinning of the spinner table 92, and the frame unit U is stably held by the holding means 97.

The shape of the claw section 96 is not particularly limited, provided that the spacing L between the opposed two tip portions 96b is larger than the distance D1 between the opposed two sides of the ring frame F and is smaller than the diameter D2 of the outermost circumference of the ring frame F and that the outermost circumference of the ring frame F can be fixed by the fixing grooves 96c. As depicted in FIG. 5B, the claw section 99 may be configured in such a manner that the base portion 99a to be connected to the spinner table 92 is bent upward, and is further bent toward the center of the holding surface 94, whereby the tip portion 99b and the fixing groove 99c are formed.

The spinner table 92 is connected to the fixation recognition section 501 and the angle recognition section 502. The fixation recognition section 501 measures a load current value of a motor as the rotating means 98 rotationally driving the spinner table 92, and recognizes the load current value which varies according to a load generated when the spinner table 92 is rotated by the rotating means 98. Specifically, when the holding means 97 is rotated and the ring frame F is fixed to the fixing grooves 96c, the load current value of the motor rises, based on which the fixation recognition section 501 recognizes that the ring frame F is held by the claw sections 96.

In addition, the angle recognition section 502 includes an encoder, and recognizes a rotational angle of the motor as the rotating means 98. By this, a rotational angle θ of the holding means 97 from the start of rotation of the holding means 97 to the recognition by the fixation recognition section 501 of the fixation of the ring frame F to the fixing grooves 96c is recognized (see FIG. 6B).

The cleaning water supply nozzle 101 is provided at a tip of a horizontal pipe 102 extending horizontally from an upper end of a slewing shaft 100 erectly provided at the periphery of the spinner table 92. The cleaning water supply nozzle 101 is configured to jet cleaning water downward and to be able to be slewed on the upper side of the spinner table 92 by the slewing shaft 100. The horizontal pipe 102 has such a length that its tip reaches the center of the spinner table 92 when the cleaning water supply nozzle 101 is slewed. A cleaning water supply source (not illustrated) is connected to the horizontal pipe 102. In addition, the air supply nozzle 103 is provided at a tip of a horizontal pipe 104 extending horizontally from the upper end of the slewing shaft 100, jets air downward, and is slewed on the upper side of the spinner table 92 by the slewing shaft 100. An air supply source (not illustrated) is connected to the horizontal pipe 104.

In the spinner cleaning mechanism 9 configured in this way, when the spinner table 92 is rotated at high speed, the ring frame F of the frame unit U is fixed to the claw sections 96 of the holding means 97. Then, while spinning the spinner table 92, cleaning water is jetted from the cleaning water supply nozzle 101 and the cleaning water supply nozzle 101 is slewed in a radial direction, whereby the whole surface of the wafer W is cleaned. After the cleaning, while continuing the spinning of the spinner table 92, the supply of the cleaning water from the cleaning water supply nozzle 101 is stopped, and air is supplied from the air supply nozzle 103, to blow off the cleaning water from the wafer W, whereby the wafer W is dried.

Since the frame unit U can be held by fixing the ring frame F at the claw sections 96 of the holding means 97, it is unnecessary to clamp the ring frame F by use of weight portions having a large sectional area in the centrifugal clamps. As a result, air turbulence is restrained from being generated in the cleaning case 91 during spinning of the spinner table 92.

A fixing operation for the ring frame F at the claw sections 96 will be described in detail below, referring to FIGS. 6A and 6B. FIGS. 6A and 6B are illustrations of the fixing operation for the ring frame F at the claw sections according to the present embodiment.

As illustrated in FIG. 6A, after cutting of the wafer W, the second carrying unit 40 (see FIGS. 1 and 2) suction holds the upper surface of the ring frame F of the frame unit U held by the holding table 3, and carries the frame unit U to the spinner table 92. Then, the lifting means 401 lowers the second carrying unit 40 in a direction orthogonal to the holding surface 94 of the spinner table 92, whereby the frame unit U is lowered from above the spinner table 92 to the holding surface 94.

In this instance, in a state in which the positions of the four sides of the ring frame F and the positions of the four claw sections 96 coincide with each other, the frame unit U is lowered. The tip portions 96b of the claw sections 96 are formed such that the spacing L between the opposed two tip portions 96b is larger than the distance D1 between the opposed two sides of the ring frame F and is smaller than the diameter D2 of the outermost circumference of the ring frame F (see FIG. 4A). For this reason, the frame unit U is lowered to the holding surface 94 and is accommodated inside the claw sections 96, without collision between the ring frame F and the tip portions 96b.

Next, as depicted in FIG. 6B, in a state in which the ring frame F is suction held by the second carrying unit 40, the spinner table 92 is rotated by the rotating means 98 (see FIG. 3), and the outermost circumference of the ring frame F is brought into contact with the claw sections 96. In this instance, the fixation recognition section 501 recognizes the fixation of the ring frame F at the claw sections 96, based on the load current value which varies according to the load on the rotating means 98. In addition, the angle recognition section 502 recognizes the rotational angle θ of the spinner table 92 until the fixation recognition section 501 recognizes the fixation of the ring frame F at the claw sections 96, specifically, from the start of rotation of the spinner table 92 until the rotation of the spinner table 92 stops upon contact of the ring frame F with the claw sections 96. When the rotational angle θ recognized by the angle recognition section 502 is not less than 90 degrees, the control section 50 determines that the ring frame F cannot be fixed by the claw sections 96, and causes a display section (not illustrated) to display an error.

When the fixation of the ring frame F at the claw sections 96 is recognized by the fixation recognition section 501, the suction holding of the ring frame F by the second carrying unit 40 is released, and the frame unit U is placed on the wafer holding section 93. The wafer W region of the frame unit U is suction held by the holding surface 94 through the adhesive tape T, and the adhesive tape T region between the ring frame F and the wafer W is suction held onto the adhesive tape suction surface 95.

Then, in a state in which the outermost circumference of the ring frame F is in contact with the claw sections 96, the spinner table 92 is spun. In this instance, an inertial force is generated in the ring frame F in a direction reverse to the rotating direction (arrow) of the spinner table 92, and the outermost circumference of the ring frame F continues contacting the claw sections 96. For this reason, the state in which the ring frame F is fixed to the claw sections 96 can be maintained, and lateral slippage of the frame unit U on the holding means 97 can be prevented.

When the outermost circumference of the ring frame F is in contact with the claw sections 96 in this way, the distance from the contact point between the claw section 96 and the outermost circumference of the ring frame F to the center O of the frame unit U is equal for all the claw sections 96 (see FIG. 4B). As a result, the frame unit U is held in the state of being positioned by the holding means 97, and, therefore, eccentricity of the frame unit U is prevented from occurring during spinning of the spinner table 92, and the frame unit U can be stably held by the holding means 97.

Then, cleaning water is jetted from the cleaning water supply nozzle 101 (see FIG. 3) on the upper side of the wafer W, whereby the whole surface of the wafer W is cleaned. After the cleaning, while continuing the spinning of the spinner table 92, the supply of the cleaning water is stopped, and air is supplied from the air supply nozzle 103, whereby the cleaning water is blown off from the wafer W, and the wafer W is dried. Note that the spinning direction of the spinner table 92 at the times of cleaning and drying of the wafer W is the direction of rotation of the spinner table 92 when the ring frame F is held by the claw sections 96.

In the fixation of the ring frame F by the claw sections 96, in the case where a ring frame F the same in size as the preceding frame unit U is used, when the following ring frame F is fixed by the claw sections 96, the rotational angle θ recognized by the angle recognition section 502 for the preceding ring frame F is used. By this, it is possible to omit a step of recognizing by the angle recognition section 502 the rotational angle θ of the spinner table 92 until the fixation recognition section 501 recognizes the fixation of the ring frame F at the claw sections 96 of FIG. 6B by putting the claw sections 96 in contact with the ring frame F, for the following ring frame F.

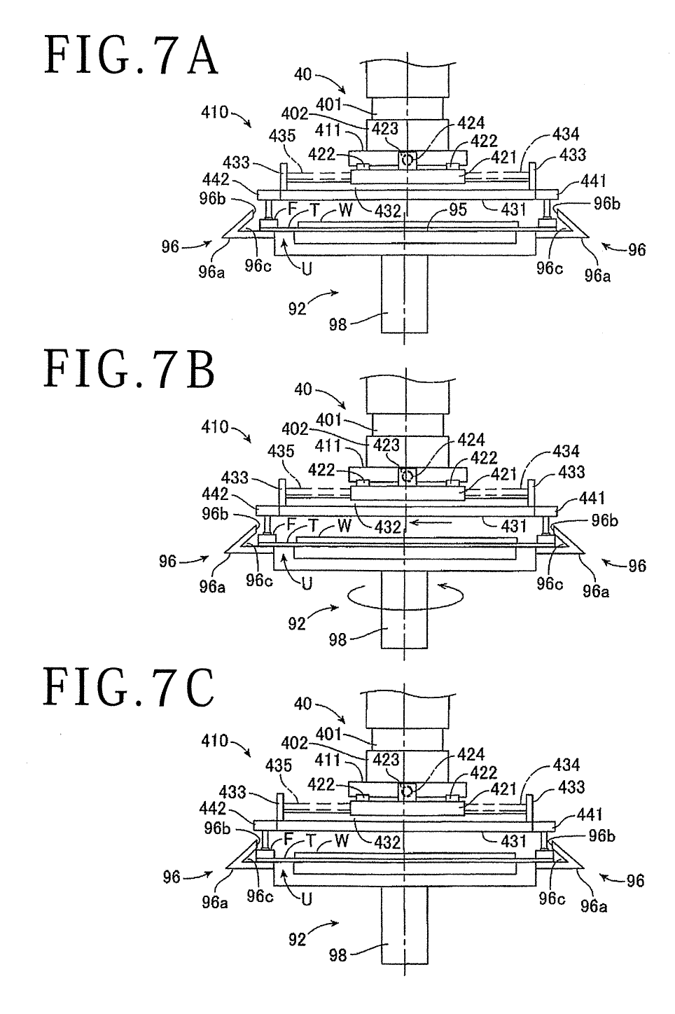

In addition, in the case where the center of the holding surface 94 of the spinner table 92 and the center of the frame unit U are not coincident with each other, the centers are made to coincide with each other by the moving unit 410 (see FIG. 2) of the second carrying unit 40. FIGS. 7A to 7C are illustrations of a center position coinciding operation of the moving unit according to the present embodiment.

As illustrated in FIG. 7A, in a state in which the upper surface of the ring frame F is suction held by the ring frame support sections 441 and 442 of the second carrying unit 40, the frame unit U is lowered to the holding surface 94, and is accommodated inside the claw sections 96. In this instance, the center of the frame unit U and the center of the holding surface 94 are out of alignment. In addition, the spring members 434 and 435 disposed on both sides of the X-axis table 421 are not expanded or contracted.

As depicted in FIG. 7B, in a state in which the ring frame F is suction held by the second carrying unit 40, the spinner table 92 is rotated by the rotating means 98, and the outermost circumference of the ring frame F is put in contact with the fixing grooves 96c of the claw sections 96. In this instance, since the center of the frame unit U and the center of the holding surface 94 are out of alignment, the ring frame F does not evenly contact the four claw sections 96, but the ring frame F contacts part of the claw sections 96.

When the ring frame F contacts the claw sections 96, the ring frame support section 441 is pushed by the claw section 96, and the X-axis table 421 is moved in the X-axis direction relative to the fixed table 411. As a result, the spring member 434 disposed near the ring frame F making contact is shrunk, whereas the spring member 435 disposed on the opposite side of the X-axis table 421 from the spring member 434 is expanded. Then, movement of the ring frame F in a direction opposite to the position of contact between the claw section 96 and the ring frame F is permitted.

By this, as depicted in FIG. 7C, the ring frame F evenly contact the four claw sections 96, and, therefore, the distance from the contact point between the fixing groove 96c and the outermost circumference of the ring frame F to the center of the frame unit U becomes equal for all the four claw sections 96 (see FIG. 4B). As a result, the center of the frame unit U and the center of the holding surface 94 coincide with each other. In this way, even in the case where the frame unit U is carried to the spinner table 92 in a state in which the center of the frame unit U and the center of the holding surface 94 are out of alignment, the moving unit 410 ensures that the frame unit U is held by the holding means 97 in an accurately positioned state. Therefore, the wafer W region of the frame unit U is disposed at the position of the holding surface 94, whereas the adhesive tape T region between the ring frame F and the wafer W is disposed at the position of the adhesive tape suction surface 95, and the frame unit U can be stably suction held by the spinner table 92.

While the present invention will be described in detail below based on an example, the description is merely for explanation, and the invention is not limited to the following example. For a case where the ring frame F of the frame unit U is fixed by use of the claw sections 96 and a case where the ring frame F is clamped by use of centrifugal clamps, comparison was made as to the generation of an air flow or flows by spinning of the spinner table 92.

FIGS. 8A and 8B are sectional views of a fixing mechanism for the ring frame and figures for explaining the air flow or flows generated when the spinner table is spun by use of the fixing mechanism. FIG. 8A is a figure illustrating a case where the claw sections of the example are used. FIG. 8B is a figure illustrating a case where the centrifugal clamps of a comparative example are used.

### EXAMPLE

The left-hand view of FIG. 8A illustrates a state in which the spinner table 92 is rotated and the ring frame F is fixed to the fixing groove 96c of the claw section 96. The sectional area of the claw section 96 is smaller than that of the centrifugal clamp 196 formed with a weight portion 198a which will be described later. The right-hand view of FIG. 8A depicts a state in which the spinner table 92 is spun, whereby the claw sections 96 fixing the ring frame F are rotated. While the rotation of the claw section 96 generates an air flow A1, the use of the claw sections 96 makes it unnecessary to fix the ring frame F by use of the weight portions 198a having a large sectional area of the centrifugal clamps 196, so that generation of air turbulence A3 (see FIG. 8B) due to the rotation of the claw sections 96 is restrained. As a result, the cleaning water blown off from the wafer W at the time of drying is prevented from being scattered by the air turbulence A3, and from adhering again to the wafer W, so that the dried state of the upper surface of the wafer W can be maintained.

### COMPARATIVE EXAMPLE

The left-hand view of FIG. 8B illustrates a state in which the ring frame F is clamped by the centrifugal clamp 196. The centrifugal clamp 196 has a configuration in which a pendulum-formed clamp portion 198 is swingably supported by a support plate 197 connected to the periphery of the spinner table 92 and extending from the spinner table 92. When the spinner table 92 is spun, the weight portion 198a on outside of the clamp portion 198 of the centrifugal clamp 196 is made to spring up by a centrifugal force, thereby to clamp the ring frame F between the claw section 198b on inside of the clamp portion 198 and the support plate 197.

Since the centrifugal clamp 196 is formed with the weight portion 198a having a large sectional area, the sectional area of the centrifugal clamp 196 is larger than the sectional area of the claw section 96 of FIG. 8A. Therefore, as depicted in the right-hand view of FIG. 8B, with the spinner table 92 spun and the centrifugal clamps 196 are rotated, an air flow A2 is generated. In addition, the rotation of the weight portions 198a having a large sectional area generates the air turbulence A3 in the vicinity of the centrifugal clamps 196. By the air turbulence A3, the cleaning water blown off from the wafer W is scattered, to drop onto and adhere again to the wafer W.

As has been described above, in the cutting apparatus 1 according to the present embodiment, the spacing L between the opposed two tip portions 96b of the claw sections 96 is formed to be larger than the distance D1 between the opposed two sides of the ring frame F and to be smaller than the diameter D2 of the outermost circumference of the ring frame F. As a result, by coinciding the positions of the four sides of the ring frame F and the positions of the four claw sections 96, the frame unit U can be placed on the holding means 97 without collision between the ring frame F and the tip portions 96b. In addition, when the frame unit U supported by the base portions 96a is rotated in a direction opposite to the direction of rotation of the holding means 97 to put the claw sections 96 into the outermost circumference of the ring frame F and the holding means 97 is rotated in this state, an inertial force is generated in the ring frame F in the direction opposite to the rotating direction of the holding means 97, resulting in that the outermost circumference of the ring frame F continues contacting the claw sections 96. For this reason, the ring frame F can be fixed to the fixing grooves 96c, and lateral slippage of the frame unit U on the holding means 97 can be prevented. In this way, since it is unnecessary to clamp the ring frame F by the centrifugal force by use of the weight portions 198a having a large sectional area of the centrifugal clamps 196, generation of the air turbulence A3 during rotation of the holding means 97 is restrained, and scattering of the liquid supplied to the wafer W by the air turbulence A3 is prevented. Therefore, contamination of the wafer W by the scattered liquid can be prevented.

While the fixation recognition section 501 recognizes that the ring frame F has been fixed to the claw sections 96 by recognizing the current value varying according to the load generated when the motor as the rotating means 98 is rotated in the above embodiment, this configuration is not limitative. A configuration in which a variation in a load when the second carrying unit 40 suction holds the ring frame F is recognized may be adopted, provided that it is recognized that the frame unit U has been fixed to the claw sections 96. When the ring frame F is fixed to the claw sections 96, a force acts in a direction for peeling the ring frame F from the second carrying unit 40, and the load at the time when the second carrying unit 40 suction holds the ring frame F is weakened. By this, it is recognized that the ring frame F has been fixed.

In addition, in the above embodiment, in the case where the ring frames F of the same size are used in the preceding frame unit U and the following frame unit U, at the time of fixing the following frame unit U by the claw sections 96, it is necessary only to preliminarily set a rotational angle θ in the preceding frame unit U. However, there may be a case where the position at which the second carrying unit 40 suction holds the frame unit U is different for the preceding frame unit U and for the following frame unit U. Therefore, in the following frame unit U, even when it is rotated by the preset rotational angle θ, the ring frame F cannot necessarily be fixed by the claw sections 96. In this case, it is necessary to rotate the spinner table 92 further by adding an angle θ₂ to the rotational angle θ, thereby bringing the claw sections 96 into contact with the ring frame F. When the spinner table 92 is rotated by adding the angle θ₂ to the rotational angle θ of the preceding frame unit U, a surplus rotational angle (see θ₄ in FIG. 100) is generated; therefore, it is sufficient to correspond to the surplus rotational angle by use of a rotatable unit provided in the second carrying unit 40.

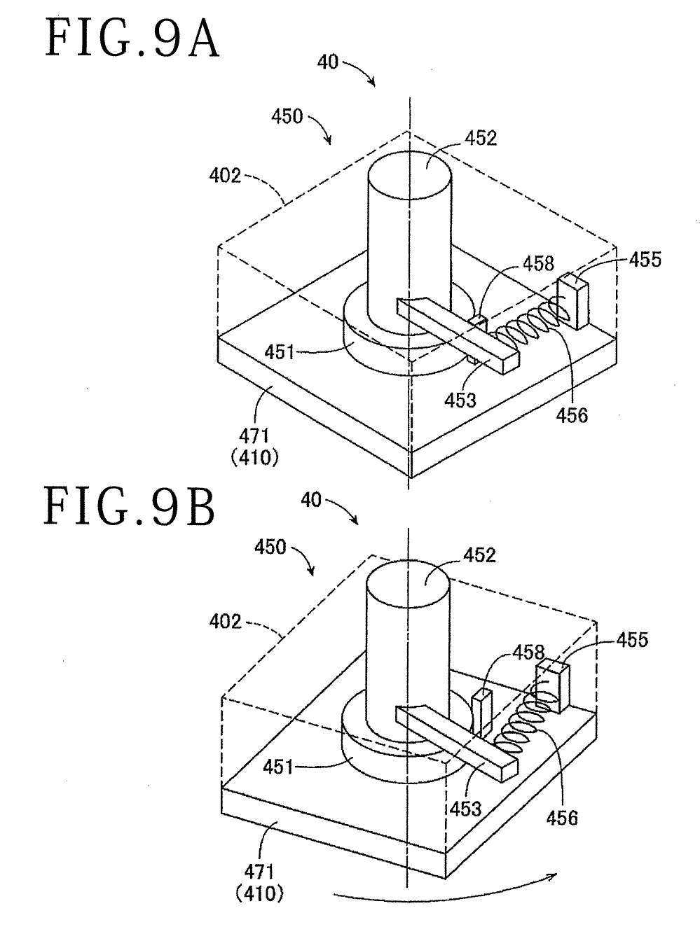

The configuration of the rotatable unit will be described in detail below, referring to FIGS. 9A and 9B. FIGS. 9A and 9B are illustrations of the rotatable unit according to the present embodiment.

As illustrated in FIG. 9A, the moving unit 410 may be provided at a lower portion of the second carrying unit 40 through a rotatable unit 450. In this case, a turntable 471 may be provided in place of the fixed table 411. An annular support section 451 (bearing) is provided in the center of the turntable 471. A fixed section 452 is disposed inside the annular support section 451, and the annular support section 451 is rotatably connected to the fixed section 452. An arm 453 projects from an outer peripheral surface of the fixed section 452. A spring support section 455 is erectly provided at an outer edge of the turntable 471, and both ends of a spring member 456 are connected respectively to opposed surfaces of the spring support section 455 and the arm 453. In addition, a stopper 458 is erectly provided in the vicinity of the annular support section 451. While a spring force for drawing toward the spring support section 455 side is acting on a tip of the arm 453, approaching of the arm 453 and the spring support section 455 is restricted by the stopper 458 erected from the turntable 471.

When the spinner table 92 (see FIG. 2) is rotated largely, as depicted in FIG. 9B, the moving unit 410 also is rotated together with the stopper 458, and the turntable 471 is rotated. In this instance, the spring support section 455 is slewed in a direction for spacing away from the arm 453 while resisting a reaction force of the spring member 456. By this, rotation of the moving unit 410 is permitted. Note that the rotatable unit 450 is energized in a rotating direction by the spring member 456, and is maintained at an origin position in the rotating direction (FIG. 9A).

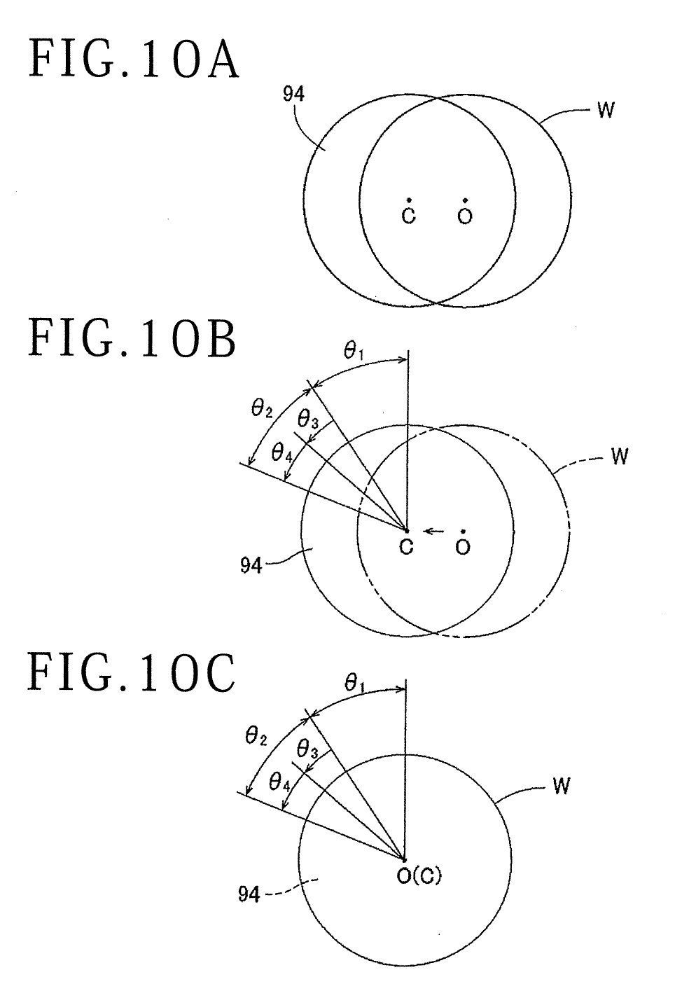

An operation of aligning the center of the holding surface 94 of the spinner table 92 and the center O of the frame unit U in the case of using the rotatable unit 450 will be described in detail below, referring to FIGS. 10A to 10C. FIGS. 10A to 10C are illustrations of an operation of the rotatable unit according to the present embodiment.

As illustrated in FIG. 10A, the frame unit U is lowered to the holding surface 94 in a state in which the upper surface of the ring frame F is suction held by the second carrying unit 40 (see FIG. 7), and is accommodated inside the claw sections 96. In this instance, in the case where the position at which the second carrying unit 40 suction holds the ring frame F is different from that for the preceding frame unit U, the position of the wafer W relative to the holding surface 94 is different from that for the preceding frame unit U. Therefore, the center O of the wafer W of the frame unit U and the center C of the holding surface 94 are out of alignment.

As depicted in FIG. 10B, the spinner table 92 is rotated, in a state in which the ring frame F is suction held by the second carrying unit 40, for bringing the outermost circumference of the ring frame F into contact with the claw sections 96. In this instance, even if the rotational angle θ₁ preset in the preceding frame unit U is used, the ring frame F cannot be fixed to the claw sections 96. In this case, the spinner table 92 is rotated by further adding the angle θ₂ to the rotational angle θ₁.

At an angle θ₃ in the course of rotation of the spinner table 92 by the angle θ₂ in addition to the angle θ₁, the ring frame F makes contact with part of the claw sections 96 (see FIG. 7B). Then, movement of the ring frame F in the X-axis direction and the Y-axis direction is permitted by the moving unit 410, whereby the center O of the wafer W of the frame unit U and the center C of the holding surface 94 are made to coincide with each other (see FIG. 7C). Therefore, at the angle θ₃ in the course of rotation to the angle θ₂, the distance from the contact point between the claw section 96 and the outermost circumference of the ring frame F to the center O of the wafer W of the frame unit U becomes equal for all the four claw sections 96 (see FIG. 4B), whereby the wafer W is positioned relative to the holding surface 94. For this reason, movement of the ring frame F in the X-axis direction and the Y-axis direction by the moving unit 410 becomes not permitted, so that a rotational angle θ₄ left until reaching the angle θ₂ cannot be permitted by the moving unit 410.

As illustrated in FIG. 100, the spinner table 92 is rotated by the angle θ₄ further from the angle θ₃, and, thus, is rotated by a total angle θ₂. In this instance, the rotatable unit 450 is rotated further after the claw sections 96 fix the ring frame F, whereby the moving unit 410 is followingly moved in the rotating direction of the spinner table 92. By this, after the center O of the wafer W and the center C of the holding surface 94 come to coincide with each other at the rotational angle θ₃, the rotation of the spinner table 92 by the surplus angle 84 can be relieved to the rotatable unit 450 side. In other words, rotation of the frame unit U by the angle θ₄ is permitted by the rotatable unit 450. Thereafter, the suction holding of the ring frame F by the second carrying unit 40 is released, and the frame unit U is transferred from the second carrying unit 40 to the spinner table 92.

In addition, while a configuration in which the present invention is used for the spinner table 92 possessed by the cutting apparatus 1 is described in the above embodiment, this configuration is not limitative. The present invention is applicable to other processing apparatuses in which a liquid is supplied to a wafer W while rotating a spinner table. For example, the present invention can be used also for a protective film coating apparatus in which a spinner table 92 is spun while supplying a liquid resin. In this case, generation of air turbulence during spinning of the spinner table 92 is restrained, whereby a surplus liquid resin blown off from the wafer W does not adhere again to the wafer W, and, therefore, a protective film uniform in thickness can be formed on the wafer W. In addition, the present invention may be applied to other processing apparatuses such as, for example, a laser processing apparatus and an expanding apparatus.

Besides, while each embodiment of the present invention has been described above, other embodiments of the present invention may total or partial combinations of the above-described embodiments.

In addition, the embodiments of the present invention are not limited to the above embodiments, and various changes, replacements and modifications are possible without departing from the gist of the technical thought of the present invention. Further, if the technical thought of the present invention can be realized in other ways by the progress of technology or by other derived technologies, the invention may be carried out by the relevant method. Therefore, the scope of the claims covers all the embodiments that can be included within the scope of the technical thought of the present invention.

As has been described above, the present invention has an effect that lateral slippage of the ring frame on the holding means is prevented and generation of air turbulence during rotation of the holding means is restrained, and the invention is particularly useful for a spinner table which is spun while a liquid is being supplied.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising holding means holding a frame unit, the frame unit including a ring frame formed with four sides at an interval of 90 degrees along an outer circumference of an annular plate having an opening for accommodating a wafer, the wafer accommodated in the ring frame and united with the ring frame through an adhesive tape, and the processing apparatus performing a predetermined treatment by rotating the holding means and supplying a liquid to the wafer,
wherein the holding means includes:
a wafer holding section adapted to suction hold a wafer region; and
four claw sections corresponding to the four sides of the ring frame,
each of the four claw sections includes a tip portion formed such that spacing between opposed two claw sections among the four claw sections is larger than distance between opposed two sides of the ring frame and is smaller than a diameter of an outermost circumference of the ring frame, and a base portion adapted to support the ring frame, and
wherein the base portion is formed with a fixing groove in which to fix the ring frame by rotating the accommodated frame unit in a direction opposite to a direction of rotation of the holding means.

2. The processing apparatus according to claim 1, further comprising:
a carrying unit that suction holds an upper surface of the ring frame and carries the frame unit to the holding means;
lifting means lifting up and down the carrying unit in a direction orthogonal to a holding surface of the wafer holding section; and
a control section that controls an operation of the holding means,
wherein the control section includes a fixation recognition section adapted to recognize that the ring frame is held by the carrying unit and is lowered from above the holding means by the lifting means, and the holding means is rotated in a direction for performing a predetermined treatment around a center of the holding surface, to cause the fixing grooves to fix the ring frame.

3. The processing apparatus according to claim 2,
wherein the carrying unit includes a moving unit adapted to move in a direction of the holding surface, and
a center of the frame unit and the center of the holding surface are made to coincide with each other when the fixing grooves fix the ring frame.
